(19) United States
(12) Patent Application Publication
(10) Pub. No.: US 2026/0190749 A1
(43) Pub. Date: Jul. 2, 2026

(54) DISPLAY DEVICE

(71) Applicant: LG Display Co., Ltd., Seoul (KR)

(72) Inventors: Jae Young OH, Paju-si (KR); Jae Heon YUN, Paju-si (KR); Min Uk KANG, Paju-si (KR)

(73) Assignee: LG Display Co., Ltd., Seoul (KR)

(21) Appl. No.: 19/432,492

(22) Filed: Dec. 24, 2025

(30) Foreign Application Priority Data
Dec. 30, 2024 (KR) 10-2024-0199665

(51) Int. Cl. H10K 59/65; H10K 59/131; H10K 59/38; H10K 59/40; H10K 59/80

(52) U.S. Cl. CPC H10K 59/65; H10K 59/131; H10K 59/38; H10K 59/40; H10K 59/8722; H10K 59/873; H10K 59/879; H10K 59/8792

(57) ABSTRACT

A display device can include a sensor and a display panel, where the display panel has a display area, a light-transmission area, and a boundary area surrounding the light-transmission area. The display panel includes a substrate, a circuit layer provided on the substrate, a light-emitting element layer provided on the circuit layer, an encapsulation layer provided on the light-emitting element layer, a touch sensor layer provided on the encapsulation layer, and an adhesive layer provided on the touch sensor layer. Further, at least one of a plurality of wires provided in the boundary area has a first hole overlapping the sensor.

### CROSS-REFERENCE TO RELATED APPLICATION

This application claims priority to Korean Patent Application No. 10-2024-0199665, filed in the Republic of Korea on Dec. 30, 2024, the entire contents of which is hereby expressly incorporated by reference into the present application.

### BACKGROUND

### Field

The present invention relate to a display panel and a display device including the same.

### Discussion of the Related Art

Electroluminescence display devices can be classified into inorganic light-emitting display devices and organic light-emitting displays according to a material of an emission layer. An active matrix organic light-emitting display device includes an organic light-emitting diode (OLED) that generates light by itself and has advantages in terms of a high response rate, high luminous efficiency, high luminance, and a large viewing angle. In an organic light-emitting display device, an OLED is formed at each pixel. The organic light-emitting display device has a high response rate, high luminous efficiency, high luminance, and a large viewing angle and is capable of expressing black gradation in perfect or near perfect black, thereby achieving a high contrast ratio and a high color reproduction rate.

To increase the size of a screen on which a video is implemented, a display device prepares an optical area where low-resolution pixels are provided, within the screen of the display panel, and provides electronic parts such as a camera and various sensors at a corresponding position below the optical area.

Since resolution irregularity can occur due to the low-resolution pixels in the optical area, there is a need for a display device with an improved structure to prevent or minimize resolution irregularity.

### SUMMARY OF THE DISCLOSURE

Embodiments of the present invention provide a display panel that structurally improves resolution irregularity due to low-resolution pixels, and a display device including the same.

Embodiments of the present invention provide a display panel that allows light to reach a sensor using a hole formed in a wire in the vicinity of a light-transmission area, and a display device including the same.

Embodiments of the present invention provide an improved display panel and an improved display device including the same, which address the limitations and disadvantages associated with the related art.

Objectives to be solved or addressed by embodiments of the present invention are not limited to the objectives described above, and objectives which are not described above will be clearly understood by those skilled in the art from the following descriptions.

A display device according to an embodiment the present invention includes a display panel including a display area, a light-transmission area, and a boundary area surrounding the light-transmission area; and a sensor, in which the display panel includes a substrate, a circuit layer provided on the substrate, a light-emitting element layer provided on the circuit layer, an encapsulation layer provided on the light-emitting element layer, a touch sensor layer provided on the encapsulation layer, and an adhesive layer provided on the touch sensor layer, and at least one of a plurality of wires provided in the boundary area has a first hole overlapping the sensor.

A display device according to another embodiment of the present invention includes a display panel including a display area, a light-transmission area, and a boundary area surrounding the light-transmission area; and a sensor, in which the display panel includes a substrate, a circuit layer provided on the substrate, a light-emitting element layer provided on the circuit layer, an encapsulation layer provided on the light-emitting element layer, a touch sensor layer provided on the encapsulation layer, and an adhesive layer provided on the touch sensor layer, the adhesive layer includes a body portion and a lens portion formed to protrude from a lower portion of the body portion, at least one of a plurality of wires provided in the boundary area has a first hole overlapping the sensor, and the sensor overlaps the lens portion and the first hole.

According to the embodiments of the present invention, it is possible to structurally improve resolution irregularity due to low-resolution pixels of a display panel.

According to the embodiments of the present invention, it is possible to exclude an area in which low-resolution pixels are provided corresponding to a sensor, on the display panel by allowing light to reach the sensor using the hole formed in the wire in the vicinity of the light-transmission area. Therefore, according to the embodiments of the present invention, since it is possible to structurally improve resolution irregularity due to low-resolution pixels, it is possible to improve the luminance of the display panel. As a result, it is possible to achieve low power driving of the display device with improvement of the luminance of the display panel.

According to the embodiments of the present invention, since it is possible to provide an infrared sensor positioned between two cameras to overlap the hole formed in the wire, it is possible to improve a degree of freedom in design of a space around the sensor. For example, according to the embodiments of the present invention, unlike a display panel including an infrared sensor provided apart from a camera, since the infrared sensor is provided between the two cameras, it is possible to use a space where the infrared sensor is provided apart from the camera. As a result, a degree of freedom in design of the display device can be improved.

Various useful advantages and effects of the embodiments are not limited to the above-described contents and will be more easily understood from descriptions of the specific embodiments.

### BRIEF DESCRIPTION OF THE DRAWINGS

The above and other objects, features, and advantages of the present invention will become more apparent to those of ordinary skill in the art by describing example embodiments thereof in detail with reference to the attached drawings, in which:

FIG. 1 is a diagram illustrating a display device according to one or more embodiments of the present invention;

FIG. 2 is a diagram illustrating a display area and light-transmission areas of the display panel of a display device according to one or more embodiments of the present invention;

FIG. 3 is a cross-sectional view schematically illustrating a display panel according to one or more embodiments of the present invention;

FIG. 4 is a cross-sectional view illustrating a cross-sectional structure of a pixel area provided in the display area of the display panel according to one or more embodiments of the present invention;

FIG. 5 is an example of an enlarged view illustrating the A area in FIG. 2;

FIG. 6 is an example of an enlarged view illustrating the Aa area in FIG. 5;

FIG. 7 is an example of a cross-sectional view illustrating a substrate to a touch sensor layer of the display panel taken along line I-I′ in FIG. 2;

FIG. 8 is an example of a cross-sectional view illustrating an adhesive layer and a functional layer provided on the touch sensor layer of the display panel taken along line I-I′ in FIG. 2;

FIG. 9 is a diagram illustrating a display panel according to another embodiment of the present invention taken along line I-I′ in FIG. 2;

FIG. 10 is a cross-sectional view illustrating an adhesive layer and a functional layer provided on a touch sensor layer of the display panel according to another embodiment of the present invention taken along line I-I′ in FIG. 2;

FIG. 11 is a diagram illustrating a lens portion that is provided separately in the display panel according to another embodiment of the present invention;

FIG. 12 is a cross-sectional view illustrating a cross-sectional structure of a pixel area provided in a display area of a display panel according to another embodiment of the present invention;

FIG. 13 is a diagram illustrating the display panel according to another embodiment of the present invention taken along line I-I′ in FIG. 2;

FIG. 14 is a cross-sectional view illustrating an adhesive layer and a functional layer provided on a black matrix of the display panel according to another embodiment of the of the present invention taken along line I-I′ in FIG. 2;

FIG. 15 is a cross-sectional view illustrating a cross-sectional structure of a pixel area provided in a display area of a display panel according to another embodiment of the present invention;

FIG. 16 is a diagram illustrating the display panel according to another embodiment of the present invention taken along line I-I′ in FIG. 2; and

FIG. 17 is a cross-sectional view illustrating an adhesive layer and a functional layer provided on a first insulating layer of the display panel according to another embodiment of the present invention taken along line I-I′ in FIG. 2.

### DETAILED DESCRIPTION OF THE EMBODIMENTS

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure. Further, the terms “disclosure” and “invention” used in the present specification have the same meaning and are interchangeably used herein. Also the term “can” fully encompasses all the meanings and coverages of the term “may” and vice versa.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology can unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise.

In interpreting a component, it is interpreted to include an error range even if there is no separate description.

In the case of a description of a positional relationship, for example, when the positional relationship of two parts is described as ‘on,’ ‘above,’ ‘over,’ ‘at an upper portion,’ ‘at a lower portion,’ ‘next to, and the like, one or more other parts can be located between the two parts unless ‘immediately’ or ‘directly’ is used.

In the description for the embodiments, the first, second, etc. are used to describe various components, but these components are not limited by these terms. These terms are only used to distinguish one component from another. Therefore, the first component mentioned below can be a second component within the technical spirit of the present disclosure.

Throughout the specification, the same reference numerals refer to the same component.

The features of each of the various embodiments can be combined or combined with each another, in whole or in part, and various technical interlocking and driving can be possible, and each of the embodiments can be implemented independently of each other or in conjunction with each other.

Recently, a display device as a visual information transmission medium has been further emphasized in information-oriented society, and display devices are being improved to meet requirements or needs, such as low power consumption, reduction of thickness, weight reduction, high definition, high efficiency, and the like.

In a display device according to an embodiment of the present invention, a hole can be formed in a wire bypassing a light-transmission area, and a sensor can be provided to overlap the hole. For example, an infrared sensor can be provided to overlap the hole. In this case, light can reach the sensor via the hole. Accordingly, in the display device according to one or more embodiments of the present invention, since an area where low-resolution pixels are provided corresponding to the infrared sensor can be excluded from a display panel, it is possible to prevent resolution irregularity due to low-resolution pixels.

The display device according to one or more embodiments of the present invention can include two light-transmission areas spaced at a predetermined interval. Then, the hole can be formed in the wire bypassing the light-transmission areas. Accordingly, the display device according to one or more embodiments of the present invention can include a sensor provided between the light-transmission areas separately from sensors corresponding to the light-transmission areas. For example, since the display device according to one or more embodiments of the present invention includes an infrared sensor provided between two cameras, it is possible to use a space where an infrared sensor that has been spaced apart from a camera has been provided. Therefore, a degree of freedom in design of the display device according to one or more embodiments of the present invention can be improved.

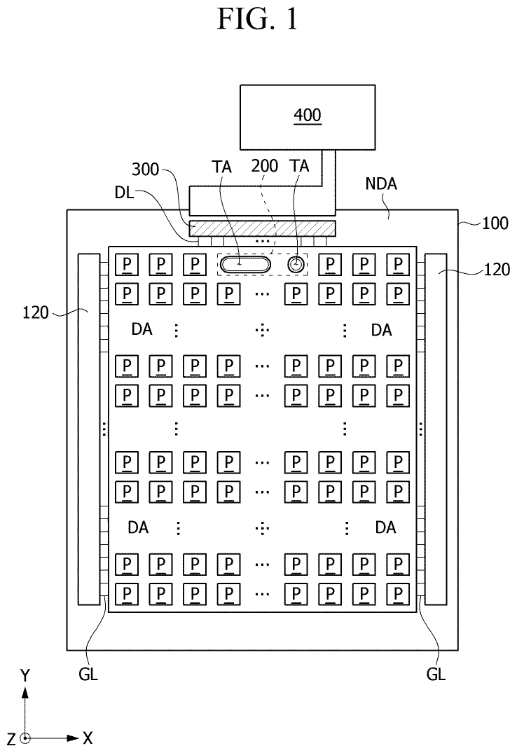

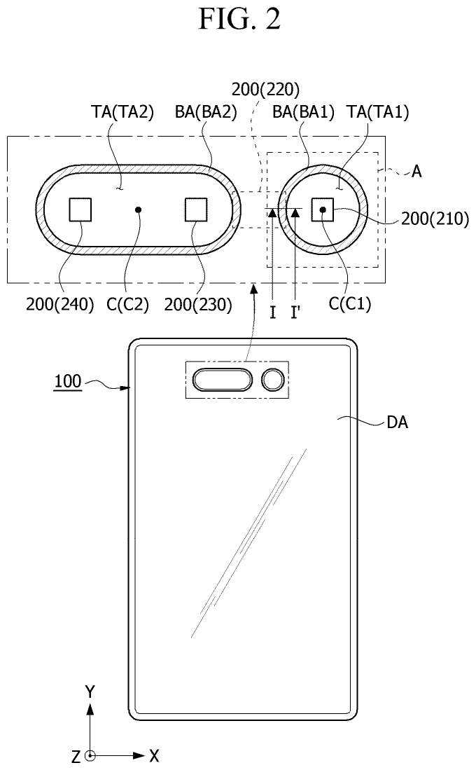

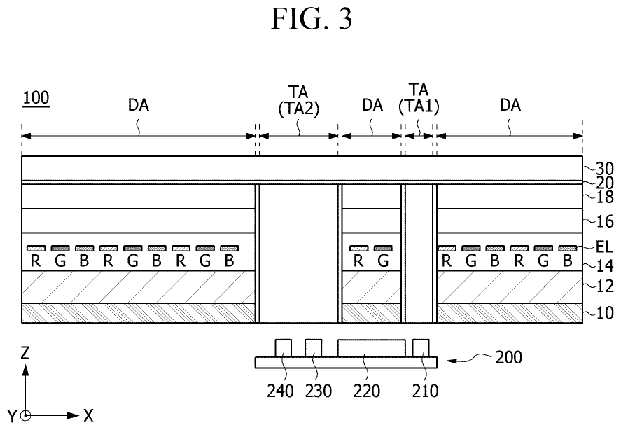

FIG. 1 is a diagram illustrating the display device according to one or more embodiments of the present invention. FIG. 2 is a diagram illustrating a display area and light-transmission areas of the display panel according to one or more embodiments of the present invention. FIG. 3 is a cross-sectional view schematically illustrating a display panel according to one or more embodiments of the present invention. In FIG. 2, reference number C can represent a center of a light-transmission area TA. In this case, a display panel 100 can include two light-transmission areas TA, reference number C1 can represent a center of a first light-transmission area TA1, and reference number C2 can represent a center of a second light-transmission area TA2.

Referring to FIGS. 1 to 3, the display device according to one or more embodiments of the present invention can include the display panel 100 on which an input video is visually reproduced, and a sensor 200. Here, the sensor 200 can include at least one of an image sensor, a proximity sensor, an illuminance sensor, a gesture sensor, a motion sensor, a fingerprint recognition sensor, and a biosensor. The sensor 200 can be a sensor module including a plurality of sensors.

The display panel 100 can include a display area DA where information, a video, and/or an image are implemented, and a non-display area NDA surrounding the display area DA. The display panel 100 can include a light-transmission area TA provided within the display area DA. The display panel 100 can include a boundary area BA provided between the display area DA and the light-transmission area TA.

The display area DA can be an area where a video is displayed. The display area DA can include a plurality of pixels P. Each of the plurality of pixels P can be configured with a plurality of sub-pixels. In each of the plurality of sub-pixels, a light-emitting element can be provided. The light-emitting element can be configured differently according to the type of the display device. For example, when the display device is an inorganic light-emitting display device, the light-emitting element can be a light emitting diode (LED), a micro light emitting diode (micro LED), or a mini light emitting diode (mini LED), but embodiments of the present specification are not limited thereto. For example, when the display device is an organic light-emitting display device, the light-emitting element can be an organic light emitting diode (OLED).

The light-transmission area TA can be an area where light enters, and can be provided within the display area DA. Here, the light-transmission area TA can have a hole structure for allowing light to enter the sensor 200 provided below the display panel 100. Here, while a case where the light-transmission area TA has a circular shape is illustrated, but embodiments of the present specification are not limited thereto. For example, the light-transmission area TA can be designed in various shapes such as a quadrangular shape, an elliptical shape, and a polygonal shape.

The light-transmission area TA can be an area in which some of a plurality of sensors 200 are disposed correspondingly. The light-transmission area TA can be an area overlapping various sensors and the like, and can have a size relatively smaller than the display area DA on which most of a video is output.

Two light-transmission areas TA can be spaced from each other at a predetermined interval. Accordingly, a part of the display area DA can be provided between the two light-transmission areas TA. For example, the light-transmission areas TA can include a first light-transmission area TA1 and a second light-transmission area TA2 spaced apart from each other. A part of the display area DA can be provided between the first light-transmission area TA1 and the second light-transmission area TA2.

The sensor 200 can be provided corresponding to the first light-transmission area TA1 and the second light-transmission area TA2. Further, the sensor 200 can be provided to overlap a part of the display area DA positioned between the first light-transmission area TA1 and the second light-transmission area TA2 in the Z-axis direction, but embodiments of the present specification are not limited thereto. For example, the sensor 200 can be provided to overlap the boundary area BA positioned between the first light-transmission area TA1 and the second light-transmission area TA2 in the Z-axis direction. Here, the sensor 200 can include a first sensor 210, a second sensor 220, a third sensor 230, and a fourth sensor 240, and the first sensor 210 can be provided corresponding to the first light-transmission area TA1. The third sensor 230 and the fourth sensor 240 can be provided corresponding to the second light-transmission area TA2. The second sensor 220 can be provided corresponding to the boundary area BA. In this case, each of the first sensor 210, the third sensor 230, and the fourth sensor 240 can be a camera (or an image sensor), but is not necessarily limited thereto. The second sensor 220 can be an infrared sensor, but is not necessarily limited thereto.

The boundary area BA can be provided to surround the light-transmission area TA. In this case, the boundary area BA can be an area where a video is not displayed, unlike the display area DA.

The boundary area BA can include a plurality of wires. For example, in the boundary area BA, a plurality of touch wires can be provided.

The boundary area BA can include a moisture permeation prevention structure such as a plurality of dams. Here, the moisture permeation prevention structure can protect the light-emitting elements of the display area DA from moisture, oxygen, or the like that can be introduced from the light-transmission area TA.

The non-display area NDA can be an area where no video is displayed. Various wires, circuits, and the like can be arranged in the non-display area NDA for driving the plurality of pixels P of the display area DA. For example, various wire and driver circuits can be mounted in the non-display area NDA, and a pad to which an integrated circuit, a printed circuit, and the like are connected can be arranged in the non-display area NDA, but embodiments of the present specification are not limited thereto.

The driver circuit can be a data driver circuit and/or a gate driver circuit, but embodiments of the present specification are not limited thereto. Wires configured to transmit control signals for controlling the driver circuits can be arranged in the display panel 100. For example, the control signals can include various timing signals including a clock signal, an input data enable signal, and synchronization signals, but embodiments of the present specification are not limited thereto. In this case, the control signals can be received through the pad.

According to the present specification, the non-display area NDA can include a bending area. Here, the bending area can be a bendable area. In this case, the remaining area of a substrate 10, excluding the bending area, can be in a flat state. In addition, the pad can be arranged on the non-display area NDA.

The display panel 100 can have a width in the X-axis direction, a length in the Y-axis direction, and a thickness in the Z-axis direction. Here, the width and length of the display panel 100 can be set to various design values depending on application fields of the display device. In addition, the X-axis direction can mean a width direction or a horizontal direction, the Y-axis direction can mean a longitudinal direction or a vertical direction, and the Z-axis direction can mean a vertical direction, a stacking direction, or a thickness direction. Here, the X-axis direction, the Y-axis direction, and the Z-axis direction can be perpendicular to each other, but can also mean different directions that are not perpendicular to each other. The X-axis direction, the Y-axis direction, and the Z-axis direction can be described as a first direction, a second direction, and a third direction, respectively. Further, the plane extended in the X-axis direction and the Y-axis direction can mean a horizontal plane.

The display panel 100 can include a circuit layer 12 disposed on the substrate 10, a light-emitting element layer 14 disposed on the circuit layer 12, a encapsulation layer 16 disposed on the light-emitting element layer 14, and a touch sensor layer 18 disposed on the encapsulation layer 16. Furthermore, the display panel 100 can include a functional layer 30 disposed on the touch sensor layer 18 via the adhesive layer 20.

The substrate 10 can be formed of an insulating material or a material having flexibility. For example, the substrate 10 can be made of glass, metal, or plastic, but is not limited thereto.

The substrate 10 can include the display area DA and the non-display area NDA. The display area DA and the non-display area NDA are not limited to being described only with respect to the substrate 10 but can be described across the entire display device.

The circuit layer 12 can include a pixel circuit connected to wirings such as data lines, gate lines, and power lines, a gate driver connected to the gate lines, and the like. Further, the circuit layer 12 can include transistors implemented with thin film transistors (TFTs) and circuit elements such as capacitors or the like.

The light-emitting element layer 14 can include a light-emitting element driven by a pixel circuit. Here, the light-emitting element can be implemented with an organic light emitting diode (OLED). The OLED can include an organic compound layer formed between an anode and a cathode. The organic compound layer includes a hole injection layer (HIL), a hole transport layer (HTL), an emission layer (EML), an electron transport layer (ETL), and an electron injection layer (EIL), but is not limited thereto.

The light-emitting element layer 14 can be covered by a protective film, and the protective film can be covered by an encapsulation layer 16. Here, the protective film can have a structure in which organic films and inorganic films are alternately stacked. In this case, the inorganic film can block penetration of moisture or oxygen. In addition, the organic film can planarize the surface of the inorganic film. When the organic film and the inorganic film are stacked in multiple layers, a movement path of moisture or oxygen is longer than that of a single layer, so that the penetration of moisture/oxygen affecting the light-emitting element layer 14 can be effectively blocked.

The encapsulation layer 16 covers the light-emitting element layer 14 so as to seal the circuit layer 12 and the light-emitting element layer 14. Here, the encapsulation layer 16 can have a multi-insulation film structure in which the organic film and the inorganic film are alternately stacked.

The touch sensor layer 18 can include capacitive touch sensors that sense a touch input based on a change in capacitance before and after the touch input. The touch sensor layer 18 can include metal wiring patterns and insulating films forming capacitance of the touch sensors. The insulating films can insulate portions in which the metal wiring patterns are intersected and planarize the surface of the touch sensor layer.

The adhesive layer 20 can be an adhesive member. Accordingly, the adhesive layer 20 allows the functional layer 30 to be attached on the touch sensor layer 18.

The functional layer 30 can be a polarizer provided on the touch sensor layer 18. The polarizer can improve visibility and a contrast ratio by converting polarization of external light reflected by metal patterns of the circuit layer 12. A cover glass can be attached on the polarizer. Here, the polarizer can be referred to as a polarization layer and can be provided in the form of a polarization film.

The functional layer 30 can be a color filter layer provided on the touch sensor layer 18. The color filter layer can include red, green, and blue color filters. The color filter layer can include a black matrix pattern. The color filter layer takes the place of a polarizer to absorb a part of a wavelength of light reflected from the circuit layer 12, thereby increasing color purity. The cover glass can be attached on the color filter layer.

The color filter layer can include an organic film that covers the color filters and the black matrix pattern. An extended portion of the organic film can cover a remaining inorganic film or the substrate 10 in a bezel area, that is, an edge area of the display panel 100.

The display device according to embodiment of the present disclosure can include the display panel 100 having a pixel array arranged on a screen, the display panel driver, etc.

The pixel array of the display panel 100 can include data lines DL, gate lines GL intersecting the data lines DL, and pixels P connected to the data lines DL and gate lines GL and arranged in a matrix.

The pixel array can be divided into a circuit layer 12 and a light-emitting element layer 14, as shown in FIG. 3. Then, a touch sensor array can be arranged on the light-emitting element layer 14. Here, each of the pixels of the pixel array can include two to four sub-pixels. Each of the sub-pixels can include a pixel circuit arranged in the circuit layer 12.

Each of the sub-pixels of the display area DA can include a pixel circuit. The pixel circuit can include a driving element to supply current to the light-emitting element (OLED), a plurality of switching elements to sample a threshold voltage of the driving element and switch a current path of the pixel circuit, a capacitor to maintain a gate voltage of the driving element, etc.

The display panel driver can write pixel data of an input image into the pixels P. The pixels can be interpreted as a pixel group including a plurality of sub-pixels.

The display panel driver can include a data driver that supplies a data voltage of pixel data to the data lines DL and a gate driver 120 that sequentially supplies gate pulses to the gate lines GL. Further, the data driver can be integrated into the drive IC 300. In addition, the display panel driver can further include a touch sensor driver omitted from the drawings.

The drive IC 300 can be bonded on the display panel 100. The drive IC 300 receives pixel data of an input image and a timing signal from the host system 400, supplies a data voltage of the pixel data to pixels, and synchronizes the data driver and the gate driver 120.

The drive IC 300 can be connected to the data lines DL through data output channels to supply data voltages of pixel data to the data lines DL. The drive IC 300 can output a gate timing signal for controlling the gate driver 120 through gate timing signal output channels.

The gate driver 120 can include a shift register formed on a circuit layer of the display panel 100 together with a pixel array. The shift register of the gate driver 120 can sequentially supply gate signals to the gate lines GL under the control of the timing controller. The gate signal can include a scan pulse and an EM pulse of an emission signal.

The host system 400 can be implemented with an application processor (AP). The host system 400 can transmit pixel data of an input image to the drive IC 300 through a mobile industry processor interface (MIPI). For example, the host system 400 can be connected to the drive IC 300 through a flexible printed circuit (FPC).

Meanwhile, the display panel 100 can be implemented with a flexible panel applicable to a flexible display.

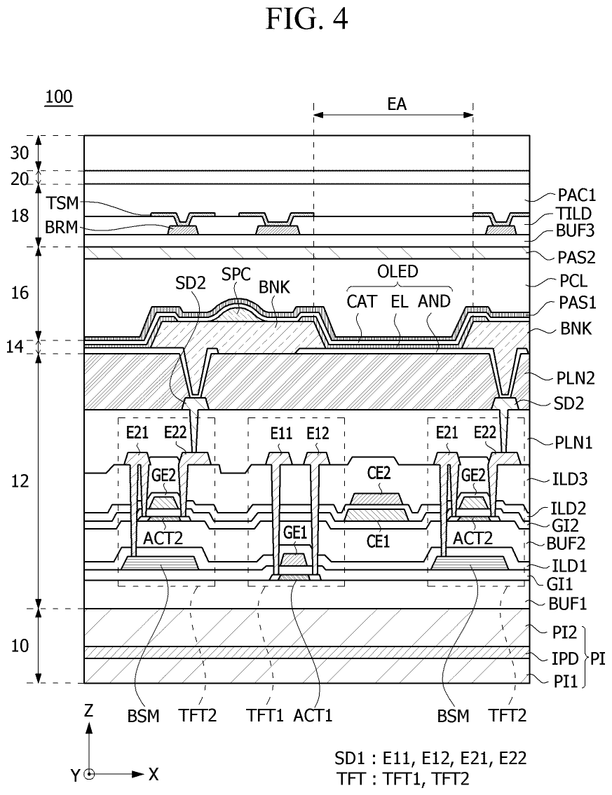

FIG. 4 is a cross-sectional view conceptually illustrating a cross-sectional structure of a pixel area disposed in a display area of a display panel according to one embodiment of the present invention. Here, it should be noted that the cross-sectional structure of the pixel area is not limited to that of FIG. 4. In FIG. 4, TFT can represent a driving element of the pixel circuit. In detail, TFT1 can be a first TFT that is one of Lower Temperature Poly-Silicon (LTPS) TFTs disposed in the display area, and TFT2 can be a second TFT that is one of oxide TFTs disposed in the display area.

Referring to FIG. 4, a plurality of pixel circuits and wires connected to the pixel circuits can be disposed in the display area DA of the display panel 100. Here, the pixel circuits of the display area can include a pixel circuit of a red sub-pixel driving a red light-emitting element, a pixel circuit of a green sub-pixel driving a green light-emitting element, and a pixel circuit of a blue sub-pixel driving a blue light-emitting element.

The substrate PI can include first and second substrates PI1 and PI2. In addition, an inorganic film IPD can be formed between the first substrate PI1 and the second substrate PI2. In this case, the inorganic film IPD can block moisture permeation. Here, since the substrate PI can be formed of polyimide, it can be referred to as a PI substrate, and the first and second substrates PI1 and PI2 can be referred to as first and second PI substrates.

The first buffer layer BUF1 can be formed on the second substrate PI2. The first buffer layer BUF1 can be formed of a multi-layered insulating layer in which two or more oxide layers SiO₂ and nitride layers SiNx are stacked. A first semiconductor layer is formed on the first buffer layer BUF1. The first semiconductor layer can include a polysilicon semiconductor layer patterned in a photolithography process. The first semiconductor layer can include a polysilicon active pattern (a first active pattern) ACT1 forming a semiconductor channel in the first TFT TFT1.

A first gate insulating layer GI1 is deposited on the first buffer layer BUF1 to cover the first active pattern ACT1 of the first semiconductor layer. The first gate insulating layer GI1 includes an inorganic insulating material layer. A first metal layer is formed on the first gate insulating layer GI1. The first metal layer is insulated from the first semiconductor layer by the first gate insulating layer GI1.

The first metal layer can include a single metal layer patterned in a photolithography process or metal patterns in which two or more metal layers are stacked. The first metal layer can include the gate electrode GE1 of the first TFT TFT1 and a light shield pattern BSM under the second TFT TFT 2.

A first interlayer insulating layer ILD1 is formed on the first gate insulating layer GI1 to cover the patterns of the first metal layer. The first interlayer insulating layer ILD1 can include an inorganic insulating material. A second buffer layer BUF2 is formed on the first interlayer insulating layer ILD1. The second buffer layer BUF2 can include a single layer or a multi-layer inorganic insulating material.

A second semiconductor layer is formed on the second buffer layer BUF2. The second semiconductor layer can include an oxide active pattern (a second active pattern) ACT2 forming a semiconductor channel in the second TFT TFT2. The second gate insulating layer GI2 can be deposited on the second buffer layer BUF2 to cover the second active pattern ACT2 of the second semiconductor layer. The second gate insulating layer GI2 can include a single or multi-layered inorganic insulating material. A second metal layer can be formed on the second gate insulating layer GI2. The second metal layer can be insulated from the second semiconductor layer by the second gate insulating layer GI2.

The second metal layer can include a single metal layer patterned in a photolithography process or metal patterns in which two or more metal layers are stacked. The second metal layer can include a gate electrode GE2 of the second TFT TFT2 and a lower capacitor electrode CE1.

A second interlayer insulating layer ILD2 can be formed on the second gate insulating layer GI2 to cover the patterns of the second metal layer. The second interlayer insulating layer ILD2 can include a single layer or a multi-layer inorganic insulating material. A third metal layer can be formed on the second interlayer insulating layer ILD2. The third metal layer can be insulated from the second metal layer by the second interlayer insulating layer ILD2.

The third metal layer can include a single metal layer patterned in a photolithography process or metal patterns in which two or more metal layers are stacked. The third metal layer can include an upper capacitor electrode CE2. The capacitor Cst of the pixel circuit can be composed of the upper capacitor electrode CE2, the lower capacitor electrode CE1, and a dielectric layer therebetween, that is, the second interlayer insulating layer ILD2.

A third interlayer insulating layer ILD3 covering the patterns of the third metal layer can be formed on the second interlayer insulating layer ILD2. The third interlayer insulating layer ILD3 can include a single layer or a multi-layer inorganic insulating material. A fourth metal layer can be formed on the third interlayer insulating layer ILD3. The fourth metal layer can be insulated from the second semiconductor layer by the second gate insulating layer GI2, the second interlayer insulating layer ILD2 and the third interlayer insulating layer ILD3.

A fourth metal layer can include a single metal layer patterned in a photolithography process or metal patterns in which two or more metal layers are stacked. The fourth metal layer can include first and second electrodes E11 and E12 of the first TFT TFT1 and first and second electrodes E21 and E22 of the second TFT TFT2, and can be a metal pattern SD1 of FIG. 4. The first and second electrodes E11 and E12 of the first TFT TFT1 can be connected to a first active pattern ACT1 through a first contact hole passing through the insulating layers GI1, ILD1, BUF2, GI2, ILD2 and ILD3. The first and second electrodes E21 and E22 of the second TFT TFT2 can be connected to a second active pattern ACT2 through a second contact hole passing through the insulating layers GI2, ILD2 and ILD3. The first electrode E21 of the second TFT TFT2 can be connected to the light shield pattern BSM through a third contact hole passing through the insulating layers ILD1, BUF2, GI2, ILD2 and ILD3.

A first planarization layer PLN1 can cover the metal pattern SD1 of the fourth metal layer. The first planarization layer PLN1 can thickly cover the display area DA of the circuit layer 12 with an organic insulating material. When the first planarization layer PLN1 is applied on the circuit layer 12, the organic insulating material can flow to the edge of the display panel 100 and cover the side surface of the circuit layer 12.

A fifth metal layer can be formed on the first planarization layer PLN1. The fifth metal layer can be insulated from the fourth metal layer by the first planarization layer PLN1. The fifth metal layer can include a single metal layer patterned in a photolithography process or metal patterns in which two or more metal layers are stacked. The fifth metal layer can include a metal pattern SD2 connecting the light-emitting element to the second TFT TFT2. The metal pattern SD2 can be connected to the second electrode E22 of the second TFT TFT2 through a fourth contact hole penetrating the first planarization layer PLN1.

A second planarization layer PLN2 can be formed on the first planarization layer PLN1 to cover the metal patterns of the fifth metal layer. The second planarization layer PLN2 can thickly cover the display area DA of the circuit layer 12 with an organic insulating material. A sixth metal layer can be formed on the second planarization layer PLN2. The second planarization layer PLN2 can planarize the surface on which the sixth metal layer is formed.

The sixth metal layer can include a single metal layer patterned in a photolithography process or metal patterns in which two or more metal layers are stacked. The pattern of the sixth metal layer can include an anode electrode AND of the light emitting element. The anode electrode AND can be in contact with the metal pattern SD2 connected to the second TFT TFT2 of the pixel circuits through the fifth contact hole penetrating the second planarization layer PLN2.

In the light emitting element layer 14, a bank BNK can be formed on the second planarization layer PLN2 to cover the edge of the anode electrode AND. In this case, the bank BNK can be formed in a pattern that divides a light emitting area (or an opening area) from which light is emitted from each pixel to the outside. Accordingly, the bank BNK can be referred to as a pixel-defining film. The bank BNK can be patterned in a photolithography process by including an organic insulating material having photosensitivity. Further, a spacer SPC having a predetermined height can be formed on the bank BNK. In this case, the bank BNK and the spacer SPC can be integrated with the same organic insulating material. Further, the spacer SPC secures a gap between a fine metal mask (FMM) and the anode electrode AND so that the FMM is not in contact with the anode electrode AND during a deposition process of the organic compound layer EL formed of an organic compound.

A seventh metal layer used as a cathode electrode CAT of the light-emitting element can be formed on the bank BNK and the organic compound layer EL. The seventh metal layer can be connected between sub-pixels in the display area DA. Here, the organic compound layer EL can be referred to as a light emitting layer or an electroluminescent layer.

The encapsulation layer 16 can include multiple insulating layers that cover the cathode electrode CAT of the light-emitting element. The multiple insulating layers can include a first inorganic insulating layer PAS1 that covers the cathode electrode CAT, a thick organic insulating layer PCL that covers the first inorganic insulating layer PAS1, and a second inorganic insulating layer PAS2 that covers the organic insulating layer PCL. Here, the organic insulating layer PCL can be a first organic insulating layer.

The touch sensor layer 18 can include a third buffer layer BUF3 that covers the second inorganic insulating layer PAS2, a bridge metal BRM provided on the third buffer layer BUF3, an inorganic touch interlayer insulating layer TILD that covers the bridge metal BRM, a touch sensor metal TSM provided on the inorganic touch interlayer insulating layer TILD, and a first insulating layer PAC1 that covers the touch interlayer insulating layer TILD and the touch sensor metal TSM. Here, the third buffer layer BUF3 can be a touch buffer layer. The first insulating layer PAC1 can include an organic insulating material and can be a second organic insulating layer or a touch insulating layer.

An eighth metal layer that is used as the bridge metal BRM can be provided on the third buffer layer BUF3 and can overlap the bank BNK. The eighth metal layer can include a single metal layer patterned in a photolithography process or metal patterns in which two or more metal layers are stacked.

A ninth metal layer can include a single metal layer patterned in a photolithography process or metal patterns in which two or more metal layers are stacked. The pattern of the ninth metal layer can include the touch sensor metal TSM. The touch sensor metal TSM can be in contact with the bridge metal BRM through a sixth contact hole penetrating the touch interlayer insulating layer TILD.

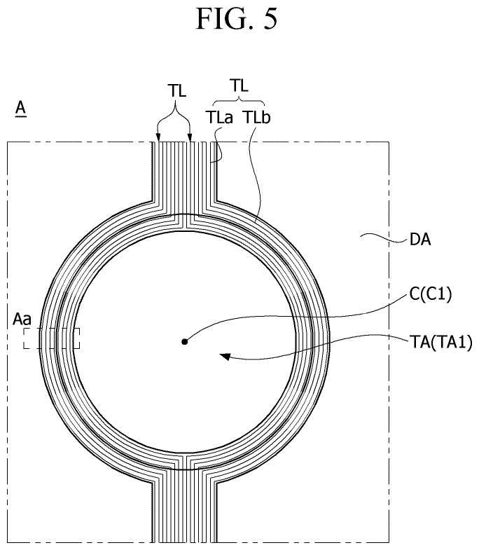

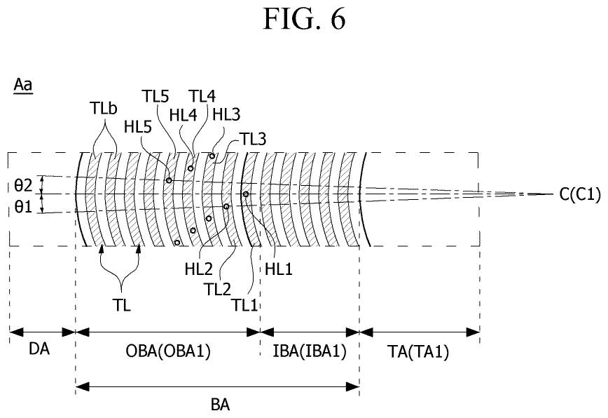

FIG. 5 is an enlarged view illustrating the A area in FIG. 2. FIG. 6 is an enlarged view illustrating the Aa area in FIG. 5.

Referring to FIGS. 5 and 6, the light-transmission area TA to which the sensor 200 corresponds can be formed in a circular shape and the boundary area BA can be provided in the vicinity of the light-transmission area TA, but embodiments of the present specification are not necessarily limited thereto. For example, the light-transmission area TA can have various shapes such as a polygonal shape and an elliptical shape, and the shape of the boundary area BA can also change corresponding to the shape of the light-transmission area TA.

In the boundary area BA, wires TL that bypass the light-transmission area TA can be provided. In this case, the boundary area BA can be an area where a video is not displayed, unlike the display area DA.

The wire TL can include a linear portion TLa and a curved portion TLb extending from one side of the linear portion TLa. In this case, the curved portion TLb can extend in a circumferential direction with the center C of the light-transmission area TA as a reference. For example, the curved portion TLb can be arranged along a curve with a predetermined radius of curvature with the center C of the light-transmission area TA as reference.

In the wire TL, at least one hole HL can be provided in the curved portion TLb and can overlap the second sensor 220. Here, the hole HL of the wire TL can penetrate the wire TL in the Z-axis direction. In this case, the hole HL can be formed inside the wire TL, but embodiments of the present specification are not necessarily limited thereto. For example, the hole HL can be formed in contact with an edge of the wire TL. Accordingly, the hole HL can be provided as a groove formed to be recessed on the edge of the wire TL in a plane view. The hole HL of the wire TL can be a first hole, a light-transmission hole, a wire hole, a touch wire hole, or a line hole.

The wire TL can be a touch wire. For example, the wire TL can be configured with metal patterns that form the capacitance of the touch sensors. For example, the wire TL can be formed of at least one of materials that compose the bridge metal BRM and the touch sensor metal TSM.

The boundary area BA can include an inside boundary area IBA and an outside boundary area OBA. For example, a first boundary area BA1 (see FIG. 2) can be provided in the periphery of the first light-transmission area TA1, and a second boundary area BA2 (see FIG. 2) can be provided in the periphery of the second light-transmission area TA2. Here, the inside can represent a direction toward the center C of the light-transmission area TA with the light-transmission area TA as a reference, and the outside can represent a direction opposite to the outside.

The inside boundary area IBA can be provided to surround the light-transmission area TA, and the outside boundary area OBA can be provided to surround the inside boundary area IBA. In this case, the display area DA can be provided in the periphery of the outside boundary area OBA. In detail, first inside boundary area IBA1 can be provided outside the first light-transmission area TA1. A first outside boundary area OBA1 can be provided outside the first inside boundary area IBA1. The display area DA can be provided in the periphery of the first outside boundary area OBA1. That is, the first inside boundary area IBA1 can be provided between the first outside boundary area OBA1 and the first light-transmission area TA1. In this case, like the first boundary area BA1 of the first light-transmission area TA1, a second boundary area BA2 provided outside the second light-transmission area TA2 can also include an inside boundary area IBA and an outside boundary area OBA.

The holes HL of the wire TL can be provided in the outside boundary area OBA. Here, the wire TL in which the hole HL is formed can be referred to as a light-transmission wire.

When the holes HL of the wire TL are provided in the inside boundary area IBA, light that is introduced inside the display panel 100 via the hole HL of the wire TL can affect a camera that is provided as the first sensor 210. Accordingly, in the display device according to one or more embodiments of the present invention, it is possible to prevent or minimize introduction of light to the first sensor 210 via the hole HL of the wire TL by providing the holes HL of the wire TL in the outside boundary area OBA.

Among a plurality of wires TL, the light-transmission wires in which the hole HL is formed can be provided in the outside boundary area OBA. The light-transmission wires can be spaced from each other on a radial direction with the center C of the light-transmission area TA as a reference.

The light-transmission wires can include a first light-transmission wire TL1 in which a first light-transmission hole HL1 is provided, a second light-transmission wire TL2 in which a second light-transmission hole HL2 is provided, a third light-transmission wire TL3 in which a third light-transmission hole HL3 is provided, a fourth light-transmission wire TL4 in which a fourth light-transmission hole HL4 is provided, and a fifth light-transmission wire TL5 in which a fifth light-transmission hole HL5 is provided, but embodiments of the present specification are not necessarily limited thereto. To increase an amount of light that reaches the second sensor 220, more light-transmission wires can be provided in the outside boundary area OBA.

The light-transmission holes HL1, HL2, HL3, HL4, and HL5 provided in the respective light-transmission wires TL1, TL2, TL3, TL4, and TL5 can be provided not to overlap each other in the radial direction. For example, the light-transmission holes HL1, HL2, HL3, HL4, and HL5 can be spaced apart from each other in the circumferential direction with the center C of the light-transmission area TA as a reference. Accordingly, the first light-transmission hole HL1 and the second light-transmission hole HL2 can form a predetermined first angle θ1 with the center C of the light-transmission area TA as a reference. The first light-transmission hole HL1 and the fifth light-transmission hole HL5 can form a predetermined second angle θ2 with the center C of the light-transmission area TA as a reference. Accordingly, the display panel 100 can ensure a uniform and sufficient amount of light via the light-transmission holes HL1, HL2, HL3, HL4, and HL5 that are provided not to overlap each other. Here, the first angle θ1 and the second angle θ2 can be the same, but embodiments of the present specification are not necessarily limited thereto.

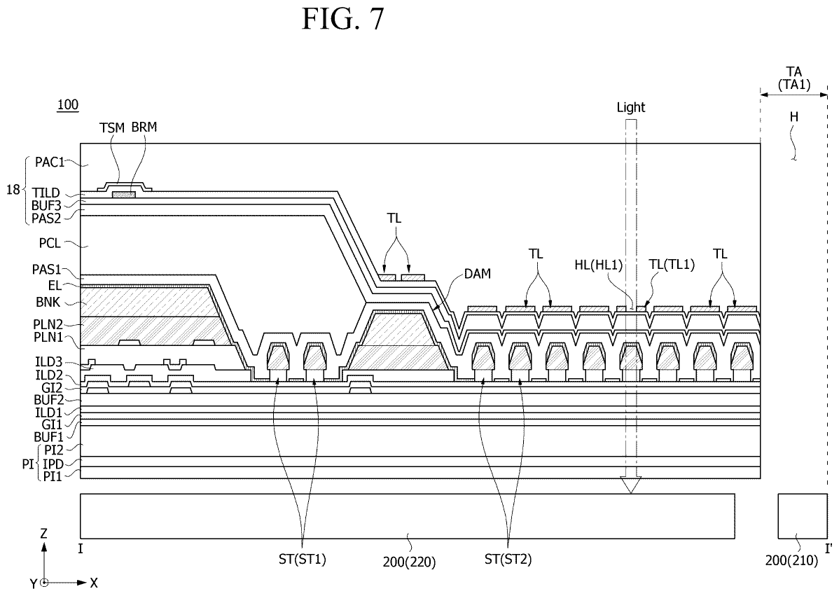

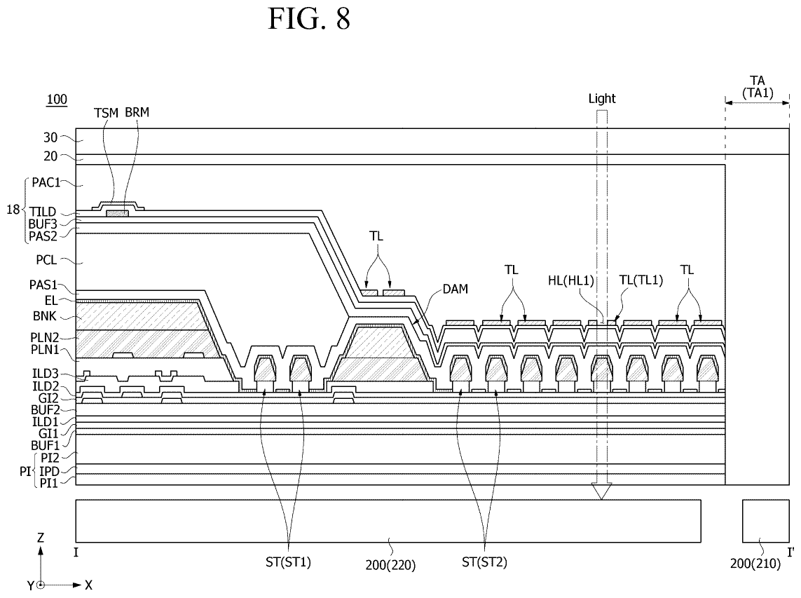

FIG. 7 is a cross-sectional view illustrating a substrate to a touch sensor layer of the display panel taken along line I-I′ in FIG. 2. FIG. 8 is a cross-sectional view illustrating an adhesive layer and a functional layer provided on the touch sensor layer of the display panel taken along line I-I′ in FIG. 2. For example, FIG. 8 is a cross-sectional view illustrating the substrate to the functional layer of the display panel. Here, FIG. 8 can illustrate a display panel 100 according to a first embodiment that is provided in the display device according to one or more embodiments of the present invention.

The configurations of the boundary area BA can include partial configurations of the substrate PI, the circuit layer 12 on the substrate PI, the light-emitting element layer 14 on the circuit layer 12, the encapsulation layer 16 on the light-emitting element layer 14, and the touch sensor layer 18 on the encapsulation layer 16, which are provided in the pixel area. For example, partial configurations of the substrate PI, the circuit layer 12, the light-emitting element layer 14, the encapsulation layer 16, and the touch sensor layer 18 provided in the pixel area can extend to the boundary area BA. Further, the configurations of the boundary area BA can be formed by processes of forming the partial configurations of the substrate PI, the circuit layer 12, the light-emitting element layer 14, the encapsulation layer 16, and the touch sensor layer 18. Accordingly, configurations the substantially same as those in the pixel area of the display area DA described with reference to FIG. 4 in terms of an arrangement structure are represented by the same reference numbers, and redundant description thereof will not be repeated or will be simplified.

The light-transmission area TA can include a hole structure H for allowing light to enter the sensor 200 provided below the display panel 100. For example, the first light-transmission area TA1 can include a hole structure for allowing light to enter the first sensor 210 provided below the display panel 100.

Referring to FIGS. 4, 7, and 8, the boundary area BA can include a moisture permeation prevention structure such as a plurality of dams DAM and a plurality of protrusion patterns ST. Accordingly, the moisture permeation prevention structure can protect the light-emitting elements of the display area DA from moisture, oxygen, or the like that can be introduced from the light-transmission area TA.

The dams DAM and the protrusion patterns ST can be provided on the second interlayer insulating layer ILD2.

The dams DAM and the protrusion patterns ST can be formed using a plurality of layers provided in the display area DA or a plurality of layers extending from the display area DA. In this case, the number of dams DAM and the number of protrusion patterns ST are not particularly limited.

The dams DAM and the protrusion patterns ST can be provided in a closed loop shape surrounding the light-transmission area TA. Accordingly, the dams DAM and the protrusion patterns ST can prevent permeation of moisture or the like into the display area DA via the light-transmission area TA.

The plurality of protrusion patterns ST can be spaced apart from each other on the second interlayer insulating layer ILD2, but embodiments of the present specification are not necessarily limited thereto. In this case, the protrusion patterns ST can include first protrusion patterns ST1 provided on the display area DA side and second protrusion patterns ST2 provided on the light-transmission area TA side, with the dam DAM as a reference. Accordingly, a plurality of first protrusion patterns ST1 can be provided between the display area DA and the dam DAM, and a plurality of second protrusion patterns ST2 can be provided between the dam DAM and the light-transmission area TA. In this case, the first protrusion patterns ST1 can overlap the organic insulating layer PCL.

The dam DAM can be provided between the plurality of first protrusion patterns ST1 and the plurality of second protrusion patterns ST2, and can be formed to have a height higher than the protrusion patterns ST with the second interlayer insulating layer ILD2 as a reference. Accordingly, since the dam DAM increases a length of a path through which oxygen, moisture, or the like permeates, it is possible to more effectively block oxygen, moisture, or the like that is introduced via the light-transmission area TA.

The dam DAM can include the same material as the material for forming the third interlayer insulating layer ILD3, the second planarization layer PLN2, the bank BNK, the organic compound layer EL, and the first inorganic insulating layer PAS1, but embodiments of the present specification are not necessarily limited thereto. For example, the dam DAM can include a metal layer. The dam DAM can include the first planarization layer PLN1 instead of the third interlayer insulating layer ILD3.

The dam DAM can be formed through the same process as the process of forming the third interlayer insulating layer ILD3, the second planarization layer PLN2, the bank BNK, the organic compound layer EL, and the first inorganic insulating layer PAS1, but embodiments of the present specification are not necessarily limited thereto.

The protrusion patterns ST can include the same material as the material for forming the third interlayer insulating layer ILD3, the second planarization layer PLN2, the organic compound layer EL, and the first inorganic insulating layer PAS1, but embodiments of the present specification are not necessarily limited thereto. For example, the protrusion patterns ST can include a metal layer. The protrusion patterns ST can include the first planarization layer PLN1 instead of the third interlayer insulating layer ILD3. In this case, the protrusion patterns ST can include an undercut shape such as a “T” shape or an “I” shape through an etching process.

The wires TL can be provided to overlap the dam DAM and/or the protrusion patterns ST. In this case, the wires TL can be provided on the touch interlayer insulating layer TILD positioned on the dam DAM and/or the protrusion patterns ST.

The wires TL can be formed in the same process as the process of forming the touch sensor metal TSM that is provided as the ninth metal layer, but embodiments of the present specification are not necessarily limited thereto. For example, the wires TL can be provided on the third buffer layer BUF3 positioned on the dam DAM and/or the protrusion patterns ST, and in this case, the wires TL can be formed together when the bridge metal BRM that is provided as the eighth metal layer is formed.

A plurality of wires TL can include the light-transmission wire in which the light-transmission hole HL is formed. For example, the plurality of wires TL can include the first light-transmission wire TL1 in which the first light-transmission hole HL1 is provided, but embodiments of the present specification are not necessarily limited thereto. For example, the plurality of wires TL can further include at least one of second to fifth light-transmission wires TL2, TL3, TL4, and TL5 having second to fifth light-transmission holes HL2, HL3, HL4, and HL5, respectively.

As the light-transmission hole HL is formed in the light-transmission wire, light can be introduced to the second sensor 220 via the light-transmission hole HL. In this case, the light-transmission hole HL can be positioned above the protrusion pattern ST. As the number of light-transmission holes HL overlapping the second sensor 220 is large, the amount of light that is introduced to the second sensor 220 can be increased.

Referring to FIGS. 7 and 8, the functional layer 30 can be provided above the touch sensor layer 18 via the adhesive layer 20. In this case, the display panel 100 can include a hole structure H formed in the light-transmission area TA. A material that composes the adhesive layer 20 can be provided inside the hole structure H, but embodiments of the present specification are not necessarily limited thereto. For example, a material that is transparent but is different from the adhesive layer 20 can be provided inside the hole structure H.

The adhesive layer 20 can be provided on the first insulating layer PAC1 of the touch sensor layer 18. The adhesive layer 20 can include an epoxy-based, polyurethane-based, or polyester-based material.

The functional layer 30 can be provided on the adhesive layer 20. In this case, the functional layer 30 can be a polarization layer, and can be implemented by a polarizer in which a linear polarizer and a retardation film are bonded or a circular polarizer. The functional layer 30 can be a polarization film.

In the display panel 100 according to the first embodiment, when the functional layer 30 is provided as a polarization film (or a polarization layer) including a low-reflection function, a black matrix BM may not be provided in the display panel 100 according to the first embodiment in terms of the function of the polarization film, but embodiments of the present specification are not necessarily limited thereto.

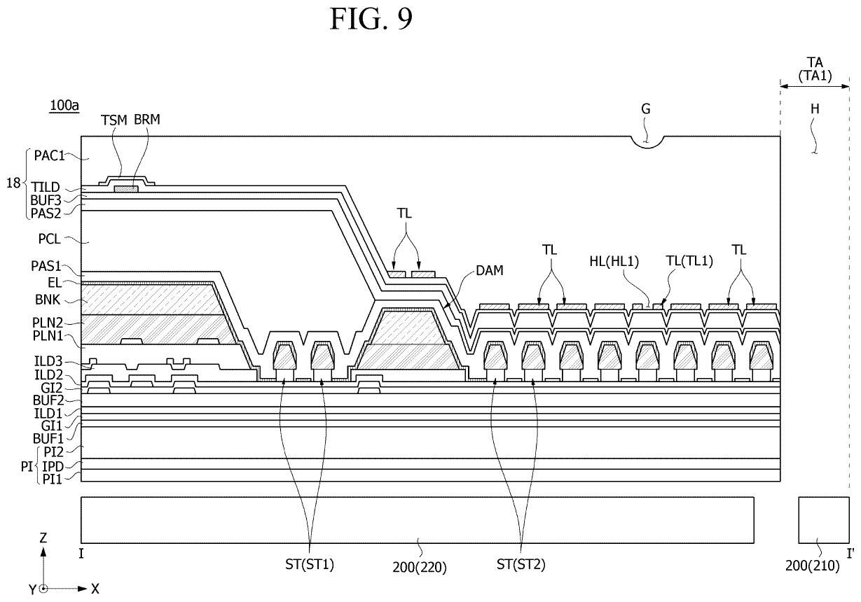

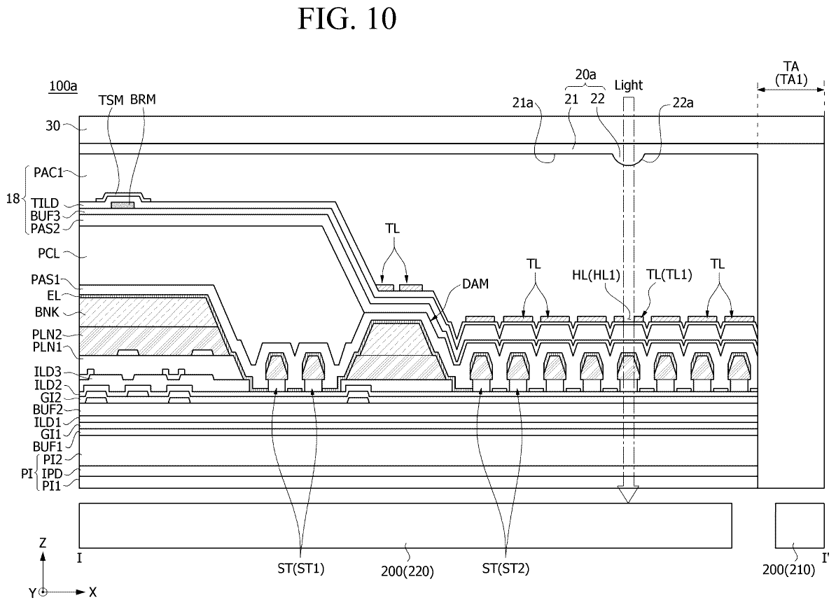

FIG. 9 is a diagram illustrating a display panel according to another embodiment of the present invention taken along line I-I′ in FIG. 2. FIG. 10 is a cross-sectional view when an adhesive layer and a functional layer provided on a touch sensor layer of the display panel according to another embodiment of the present invention taken along line I-I′ in FIG. 2. For example, FIG. 10 is a cross-sectional view of the adhesive layer and the functional layer provided in the display panel of FIG. 9. Here, FIG. 8 is a diagram illustrating the display panel 100 according to the first embodiment of the present invention, and FIGS. 9 and 10 are diagrams illustrating a display panel 100a according to a second embodiment of the present invention.

In comparison of the display panel 100 according to the first embodiment and the display panel 100a according to the second embodiment referring to FIGS. 8 to 10, the display panel 100a according to the second embodiment has a configuration in which an adhesive layer 20a can further include a lens portion 22. Accordingly, the display device according to one or more embodiments of the present invention can include the display panel 100a according to the second embodiment provided instead of the display panel 100 according to the first embodiment.

The display panel 100a according to the second embodiment can include a display area DA, light-transmission area TA, and a boundary area BA. In this case, the adhesive layer 20a including the lens portion 22 can be provided in the boundary area BA, and the lens portion 22 can overlap the hole HL of the wire TL.

In describing the boundary area BA of the display panel 100a according to the second embodiment, configurations substantially the same as those in the boundary area BA of the display panel 100 according to the first embodiment described with reference to FIGS. 7 and 8 are represented by the same reference numbers, and redundant description thereof will not be repeated or will be simplified.

Referring to FIGS. 9 and 10, the adhesive layer 20a of the display panel 100a according to the second embodiment can be provided as an adhesive member that attaches the functional layer 30 on the touch sensor layer 18. In this case, the adhesive layer 20a can include an epoxy-based, polyurethane-based, or polyester-based material.

The adhesive layer 20a can include a plate-shaped body portion 21, and the lens portion 22 formed to protrude from the body portion 21.

The body portion 21 can be formed in a plate shape, and can be provided on the first insulating layer PAC1.

The lens portion 22 can be formed to protrude from a lower surface 21a of the body portion 21 toward the second sensor 220.

The lens portion 22 can be provided on a lower portion of the body portion 21, and can be formed in a shape convex toward the second sensor 220.

The lens portion 22 can include a predetermined curved surface 22a for collecting light, and the curved surface 22a can be provided toward the second sensor 220. In detail, the curved surface 22a can be provided toward the hole HL of the wire TL. For example, the lens portion 22 can be formed in a hemispherical shape.

The lens portion 22 can be positioned in the first insulating layer PAC1.

A hemispherical grooved G can be formed in an upper surface of the first insulating layer PAC1, and an adhesive material for forming the adhesive layer 20a can be provided in the groove G. Accordingly, since the lens portion 22 can be formed corresponding to the shape of the groove G, the lens portion 22 can overlap the first insulating layer PAC1 in the X-axis direction (or the Y-axis direction).

The lens portion 22 can overlap the hole HL of the wire TL. For example, the lens portion 22 can overlap at least one of the first light-transmission hole HL1 of the first light-transmission wire TL1, the second light-transmission hole HL2 of the second light-transmission wire TL2, the third light-transmission hole HL3 of the third light-transmission wire TL3, the fourth light-transmission hole HL4 of the fourth light-transmission wire TL4, and the fifth light-transmission hole HL5 of the fifth light-transmission wire TL5. Accordingly, light collected via the lens portion 22 can reach the second sensor 220 via the hole HL of the wire TL.

The lens portion 22 can be formed to have a predetermined refractive index. In this case, the refractive index of the lens portion 22 can be greater than a refractive index of the first insulating layer PAC1. For example, the refractive index of the lens portion 22 can be equal to or greater than 1.56, and the refractive index of the first insulating layer PAC1 can be 1.3 to 1.514. In this case, the lens portion 22 and the first insulating layer PAC1 can be formed such that a difference between the refractive index of the lens portion 22 and the refractive index of the first insulating layer PAC1 is equal to or greater than 0.1 for light collection.

The body portion 21 and the lens portion 22 can be formed integrally.

The functional layer 30 provided on the adhesive layer 20a can be a polarization layer, and can be implemented by a polarizer in which a linear polarizer and a retardation film are bonded or a circular polarizer. The functional layer 30 can be a polarization film.

When the functional layer 30 in the display panel 100a according to the second embodiment is provided as a polarization film (or a polarization layer) including a low reflection function, the black matrix BM may not be provided in the display panel 100a according to the second embodiment in terms of the function of the polarization film, but embodiments of the present specification are not necessarily limited thereto.

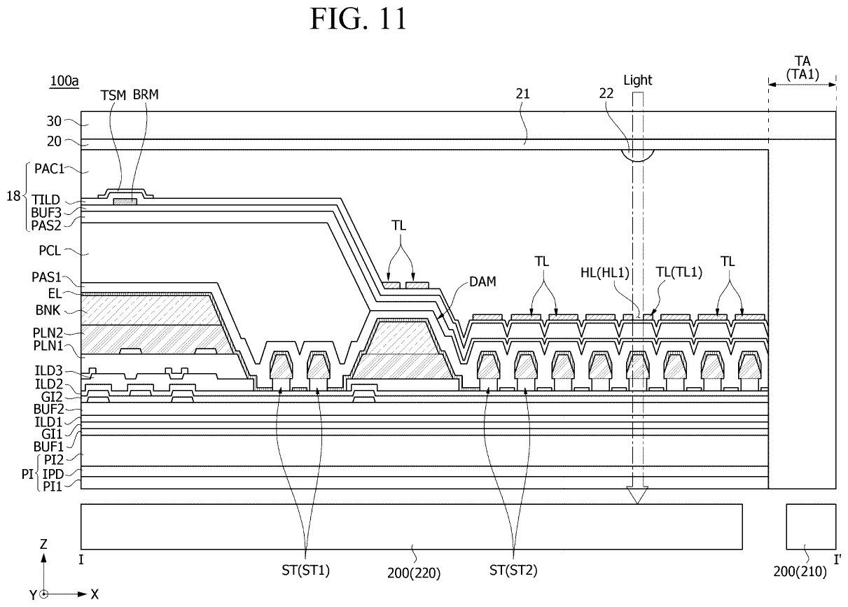

FIG. 11 is a diagram illustrating a lens portion that is provided separately in a display panel according to another embodiment of the present invention.

Referring to FIG. 11, the display device according to one or more embodiments of the present invention can include a lens portion 22 that is provided as a separate configuration. For example, a hemispherical groove G can be formed in an upper surface of the first insulating layer PAC1, and a material different from the body portion 21 can be provided in the groove G to form the separate lens portion 22. After the lens portion 22 is formed, a body portion 21 of an adhesive layer 20 formed of an adhesive material can be provided on the first insulating layer PAC1 and the lens portion 22.

The material for the lens portion 22 can be different from the material for the body portion 21. For example, the lens portion 22 can be formed using a polymer-based organic material and/or a silicon-based inorganic material.

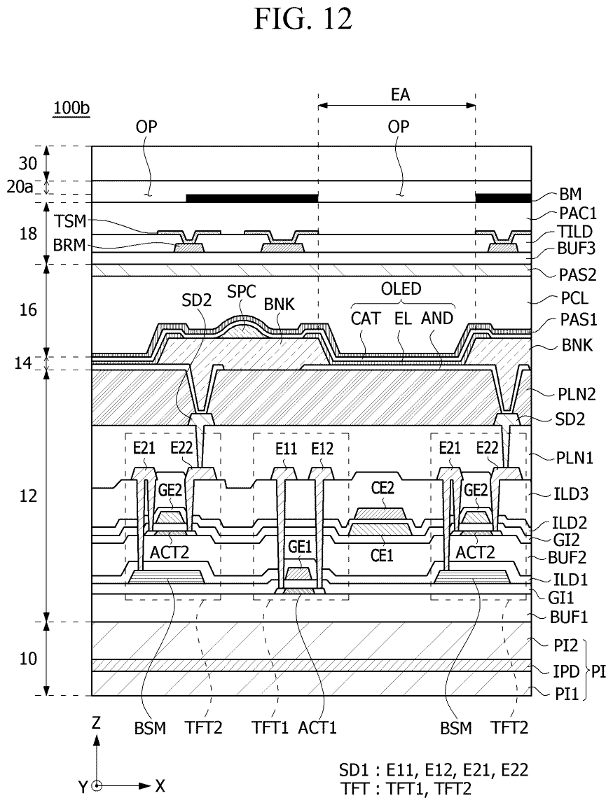

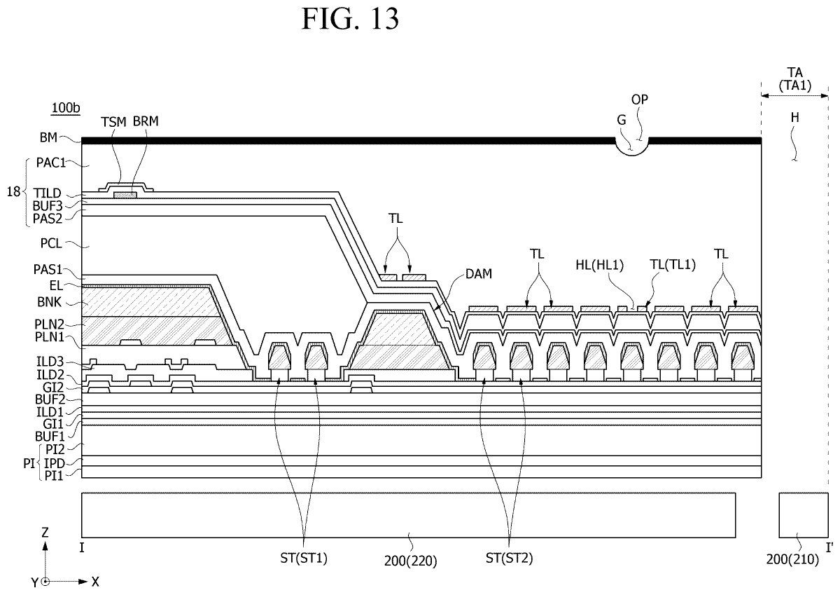

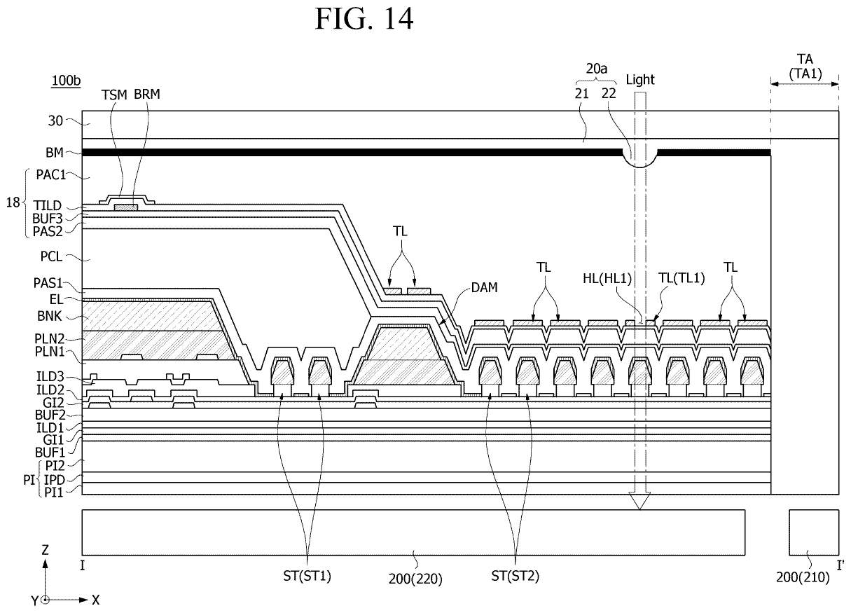

FIG. 12 is a cross-sectional view of a pixel area provided in a display area of a display panel according to another embodiment of the present invention. FIG. 13 is a diagram illustrating the display panel according to another embodiment of the present invention taken along line I-I′ in FIG. 2, and is a cross-sectional view illustrating a substrate to a black matrix of the display panel. FIG. 14 is a drawing illustrating the display panel according to another embodiment of the present invention taken along line I-I′ in FIG. 2, and is a cross-sectional view illustrating an adhesive layer and a functional layer provided on the black matrix of FIG. 13. Here, FIGS. 12 to 14 can illustrate a display panel 100b according to a third embodiment provided in the display device according to one or more embodiments of the present invention.

In comparison of the display panel 100 according to the first embodiment and the display panel 100b according to the third embodiment referring to FIGS. 4, 8, and 12 to 14, the display panel 100b according to the third embodiment can include an adhesive layer 20a including a lens portion 22, and a black matrix BM, which are provided on the first insulating layer PAC1. The display panel 100b according to the third embodiment can include a functional layer 30 that is provided as a cover glass. That is, in the display device according to one or more embodiments of the present invention, whether to provide the black matrix BM can be determined according to a function of a member provided in the functional layer 30. For example, when a cover glass or a color filter is provided as the functional layer 30, the black matrix can be provided in the display panel.

The display panel 100b according to the third embodiment can include a display area DA including a pixel area, a light-transmission area TA, and a boundary area BA.

The pixel area of the display panel 100b according to the third embodiment can include a substrate PI, a circuit layer 12 on the substrate PI, a light-emitting element layer 14 on the circuit layer 12, an encapsulation layer 16 on the light-emitting element layer 14, a touch sensor layer 18 on the encapsulation layer 16, a black matrix BM provided on the touch sensor layer 18, an adhesive layer 20a provided on the black matrix BM, and a functional layer 30 provided on the adhesive layer 20a. In this case, since the substrate PI, the circuit layer 12, the light-emitting element layer 14, the encapsulation layer 16, and the touch sensor layer 18 are substantially the same as those in the pixel area of the display area DA described with reference to FIG. 4 in terms of an arrangement structure, these are represented by the same reference numbers, and redundant description thereof will not be repeated or will be simplified. In describing the boundary area BA of the display panel 100b according to the third embodiment, configurations substantially the same as those in the boundary area BA of the display panel 100 according to the first embodiment described with reference to FIGS. 7 and 8 are represented by the same reference numbers, and redundant description thereof will not be repeated or will be simplified.

Referring to FIG. 12, the black matrix BM can be provided on the first insulating layer PAC1.

The black matrix BM can have an opening OP overlapping the emission area EA, the light-transmission area TA, and the hole HL of the wire TL. In this case, the opening OP can be provided as a hole penetrating the black matrix BM in the Z-axis direction. Here, the black matrix BM can be formed of a material having high optical density (OD). Accordingly, the black matrix BM can absorb or block light.

In the display panel 100b according to the third embodiment, unlike the display panel 100 according to the first embodiment, since a cover glass is provided as the functional layer 30 instead of a polarizer, external light can be reflected by wires provided in the circuit layer 12 and the like, thereby deteriorating the display quality of the display device.

Accordingly, the black matrix BM is provided in an area excluding the emission area EA and the light-transmission area TA, so that it is possible to prevent external light from being reflected by the wires provided in the circuit layer 12 and the like. In this case, the black matrix BM can have an opening OP overlapping the hole HL of the wire TL. Here, the opening OP overlapping the hole HL of the wire TL can be referred to as a second hole, a black matrix hole, or the like.

The opening OP can be formed by patterning using a photolithography process.

The opening OP can be provided to overlap the hole HL of the wire TL. For example, the opening OP can be formed to overlap the first light-transmission hole HL1. A plurality of wires TL can further include at least one of second to fifth light-transmission wires TL2, TL3, TL4, and TL5 having second to fifth light-transmission holes HL2, HL3, HL4, and HL5, respectively. For this reason, the black matrix BM can further have an opening OP overlapping at least one of the second to fifth light-transmission holes HL2, HL3, HL4, and HL5.

A width of the opening OP overlapping the hole HL of the wire TL can be greater than a width of the hole HL formed in the wire TL. For example, since the display panel 100b according to the third embodiment of the present invention collects light via the lens portion 22, the opening OP overlapping the hole HL of the wire TL can be formed to have the width greater than the width of the hole HL formed in the wire TL.

In the opening OP, a part of the adhesive layer 20a that composes the lens portion 22 can be provided.

Referring to FIGS. 13 and 14, a hemispherical groove G can be formed in an upper surface of the first insulating layer PAC1, and the black matrix BM can be provided on the first insulating layer PAC1. In this case, the opening OP of the black matrix BM can be formed to overlap the groove G. The opening OP of the black matrix BM can overlap the hole HL formed in the wire TL. An adhesive material for forming the adhesive layer 20a can be provided in the groove G via the opening OP. Accordingly, since the lens portion 22 can be formed corresponding to the shape of the groove G, the lens portion 22 can overlap the first insulating layer PAC1 in the X-axis direction (or the Y-axis direction).

The lens portion 22 of the display panel 100b according to the third embodiment of the present invention can be provided separately like the display panel 100a illustrated in FIG. 11.

The display panel 100b according to the third embodiment of the present invention includes the lens portion 22 as an example, but embodiments of the present specification are not necessarily limited thereto. Like the adhesive layer 20 of the display panel 100 illustrated in the FIG. 8, an adhesive layer can be implemented in a form in which the lens portion 22 is deleted.

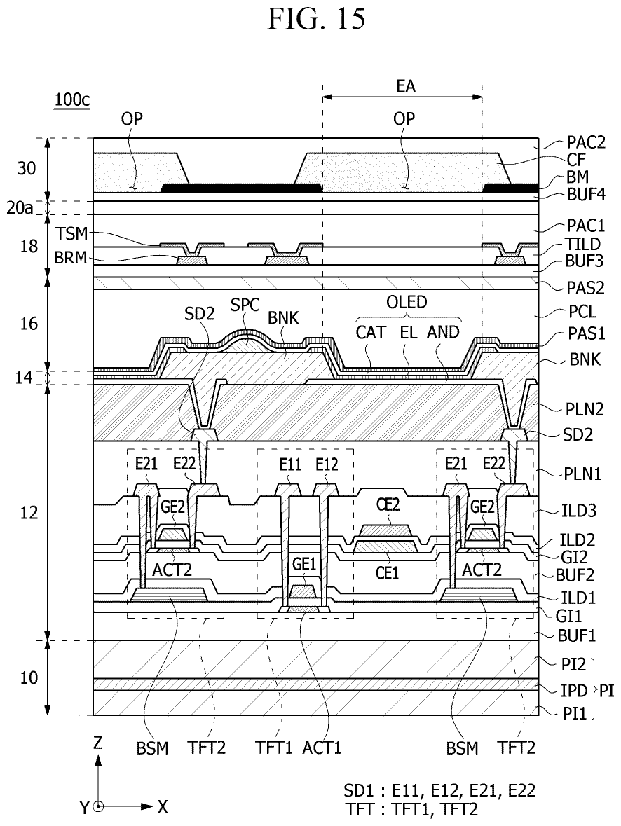

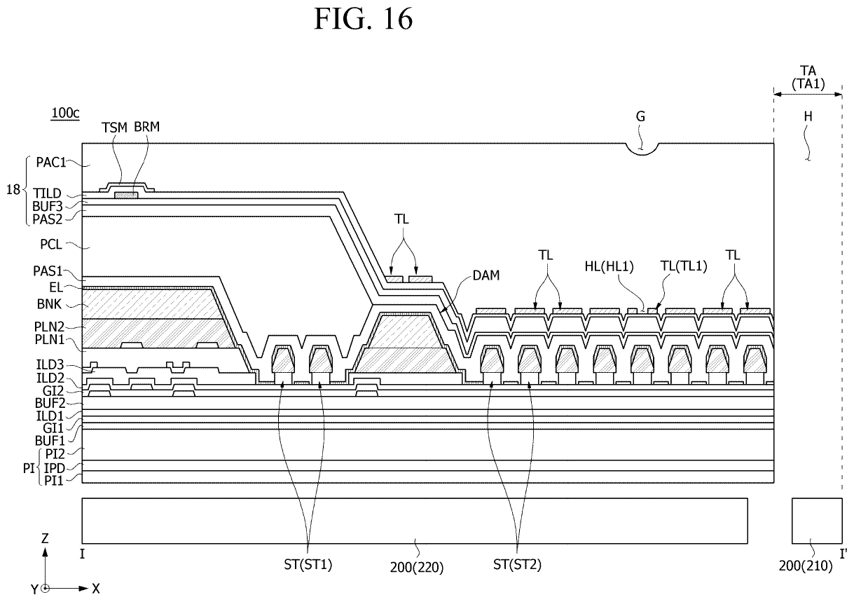

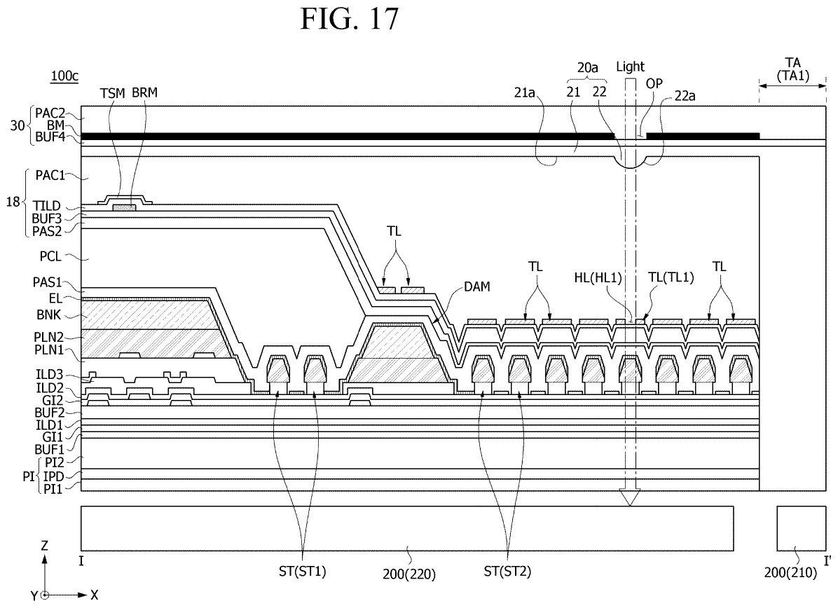

FIG. 15 is a cross-sectional view illustrating a cross-sectional structure of a pixel area provided in a display area of a display panel according to another embodiment of the present invention. FIG. 16 is a diagram illustrating the display panel according to another embodiment of the present invention taken along line I-I′ in FIG. 2, and is a cross-sectional view illustrating a substrate to a first insulating layer of the display panel. FIG. 17 is a diagram illustrating the display panel according to another embodiment of the present invention taken along line I-I′ in FIG. 2, and is a cross-sectional view illustrating an adhesive layer and a functional layer provided on the first insulating layer of FIG. 16. Here, FIGS. 15 to 17 can illustrate a display panel 100c according to a fourth embodiment provided in the display device according to one or more embodiments of the present invention.

In comparison of the display panel 100 according to the first embodiment and the display panel 100c according to the fourth embodiment referring to FIGS. 4, 8, and 15 to 17, the display panel 100c according to the fourth embodiment can include an adhesive layer 20a including a lens portion 22. Further, in the display panel 100c according to the fourth embodiment, a functional layer 30 including a color filter can be provided.

The display panel 100c according to the fourth embodiment can include a display area DA including a pixel area, a light-transmission area TA, and a boundary area BA.

The pixel area of the display panel 100c according to the fourth embodiment can include a substrate PI, a circuit layer 12 on the substrate PI, a light-emitting element layer 14 on the circuit layer 12, an encapsulation layer 16 on the light-emitting element layer 14, a touch sensor layer 18 on the encapsulation layer 16, an adhesive layer 20a provided on the touch sensor layer 18, and a functional layer 30 provided on the adhesive layer 20a. In this case, since the substrate PI, the circuit layer 12, the light-emitting element layer 14, the encapsulation layer 16, and the touch sensor layer 18 are substantially the same as those in the pixel area of the display area DA described with reference to FIG. 4 in terms of an arrangement structure, these are represented by the same reference numbers, and redundant description thereof will not be repeated or will be simplified. In describing the boundary area BA of the display panel 100c according to the fourth embodiment, configurations substantially the same as those in the boundary area BA of the display panel 100 according to the first embodiment described with reference to FIGS. 7 and 8 are represented by the same reference numbers, and redundant description thereof will not be repeated or will be simplified.

Referring to FIGS. 15 to 17, a color filter layer that increases color purity can be provided as the functional layer 30 instead of a polarizer. Accordingly, the functional layer 30 can include a color filter CF and a black matrix BM. In this case, the functional layer 30 can be provided on the adhesive layer 20a.

Referring to FIG. 15, the functional layer 30 provided in the pixel area of the display area DA can include a fourth buffer layer BUF4 provided on the adhesive layer 20a, the black matrix BM having an opening OP and the color filter CF which are provided on the fourth buffer layer BUF4, and a second insulating layer PAC2 that covers the black matrix BM and the color filter CF. Here, the fourth buffer layer BUF4 can be a color filter buffer layer. The second insulating layer PAC2 can include an organic insulating material, and can be a third organic insulating layer or a color filter insulating layer.

The fourth buffer layer BUF4 can include a single-layer or multi-layer inorganic insulating material. For example, the fourth buffer layer BUF4 can be formed of a multi-layer insulating film in which two or more oxide films (SiO₂) and nitride films (SiNx) are stacked.

The color filter CF can be provided corresponding to the emission area EA of the light-emitting element OLED, and can include any one color of red, green, and blue.

The color filter CF can include a red color filter, a green color filter, and a blue color filter matching colors of respective sub-pixels. Accordingly, the color filter CF can be provided in some of the openings OP of the black matrix BM. Further, the color filter CF can overlap the emission area EA in the Z-axis direction.

The second insulating layer PAC2 can be provided on the black matrix BM and the color filter CF. The second insulating layer PAC2 can be formed of an organic insulating material such as polyimide or acrylic resin.

Referring to FIGS. 16 and 17, the functional layer 30 in the boundary area BA and the light-transmission area TA can include the fourth buffer layer BUF4, the black matrix BM, and/or the second insulating layer PAC2, but embodiments of the present specification are not necessarily limited thereto.

The black matrix BM can be provided on the fourth buffer layer BUF4. In this case, the black matrix BM can have the opening OP overlapping the emission area EA, the light-transmission area TA, and the hole HL of the wire TL. Here, the opening OP can be provided as a hole penetrating the black matrix BM in the Z-axis direction.

Accordingly, the black matrix BM provided in the functional layer 30 is provided in an area excluding the emission area EA and the light-transmission area TA, so that it is possible to prevent external light from being reflected by wires provided in the circuit layer 12 and the like. In this case, the black matrix BM can have the opening OP overlapping the hole HL of the wire TL.

The opening OP can be formed by patterning using a photolithography process.

The opening OP can be provided to overlap the hole HL of the wire TL. For example, the opening OP can be formed to overlap the first light-transmission hole HL1. Further, plurality of wires TL can further include at least one of second to fifth light-transmission wires TL2, TL3, TL4, and TL5 having second to fifth light-transmission holes HL2, HL3, HL4, and HL5, respectively. For this reason, black matrix BM can further have the opening OP overlapping at least one of the second to fifth light-transmission holes HL2, HL3, HL4, and HL5.

A width of the opening OP overlapping the hole HL of the wire TL can be greater than a width of the hole HL formed in the wire TL. For example, since the display panel 100c according to the fourth embodiment of the present invention collects light via the lens portion 22, the opening OP overlapping the hole HL of the wire TL can be formed to have the width greater than the width of the hole HL formed in the wire TL.

Accordingly, in the display panel 100c according to the fourth embodiment, unlike the display panel 100 according to the first embodiment, the color filter layer including the color filter CF and the black matrix BM is provided as the functional layer 30 instead of a polarizer. For this reason, it is possible to prevent or minimize reflection of light by wires provided in the circuit layer 12 and the like, thereby improving the display quality of the display device. The display panel 100c according to the fourth embodiment can be easily applied to a flexible display since the color filter layer having a thickness relatively smaller than the polarizer is provided.

Referring to FIGS. 16 and 17, a hemispherical groove G can be formed in an upper surface of the first insulating layer PAC1, and an adhesive material for forming the adhesive layer 20a can be provided in the groove G. Accordingly, since the lens portion 22 can be formed corresponding to the shape of the groove G, the lens portion 22 can overlap the first insulating layer PAC1 in the X-axis direction (or the Y-axis direction). The functional layer 30 that is provided as the color filter layer can be provided on the adhesive layer 20a.

The lens portion 22 of the display panel 100c according to the fourth embodiment of the present invention can be provided as a separate configuration like the display panel 100a illustrated in FIG. 11.

The display panel 100c according to the fourth embodiment of the present invention includes the lens portion 22 as an example, but embodiments of the present specification are not necessarily limited thereto. Like the adhesive layer 20 of the display panel 100 illustrated in FIG. 8, an adhesive layer can be implemented in a form in which the lens portion 22 is deleted.

The display device according to one or more embodiments of the present specification can be described as follows.

A display device according to one or more embodiments of the present specification display device can include a display panel including a display area, a light-transmission area, and a boundary area surrounding the light-transmission area; and a sensor, in which the display panel can include a substrate, a circuit layer provided on the substrate, a light-emitting element layer provided on the circuit layer, an encapsulation layer provided on the light-emitting element layer, a touch sensor layer provided on the encapsulation layer, and an adhesive layer provided on the touch sensor layer, and at least one of a plurality of wires provided in the boundary area can have a first hole overlapping the sensor.

According to one or more embodiments of the present specification, the wire can include a curved portion provided in the vicinity of the light-transmission area, and the first hole can be provided in the curved portion.

According to one or more embodiments of the present specification, the sensor can include a first sensor overlapping the light-transmission area and a second sensor overlapping the first hole, and the second sensor can be an infrared sensor.

According to one or more embodiments of the present specification, the light-transmission area can include a first light-transmission area and a second light-transmission area spaced apart from each other, and the second sensor can overlap the display area provided between the first light-transmission area and the second light-transmission area.

According to one or more embodiments of the present specification, the adhesive layer can include a body portion provided on an insulating layer of the touch sensor layer and a lens portion formed to protrude from the body portion, and the lens portion can overlap the first hole.

According to one or more embodiments of the present specification, the body portion and the lens portion can be formed integrally.

According to one or more embodiments of the present specification, the sensor can include a first sensor overlapping the light-transmission area and a second sensor overlapping the first hole, and the lens portion can be formed convex toward the second sensor.

According to one or more embodiments of the present specification, a refractive index of the lens portion can be greater than a refractive index of the insulating layer.

According to one or more embodiments of the present specification, the lens portion can be provided in a groove formed to be recessed in an upper surface of the insulating layer.

According to one or more embodiments of the present specification, the display panel can further include a black matrix provided below the adhesive layer, and the black matrix can have a second hole overlapping the first hole.

According to one or more embodiments of the present specification, a width of the second hole can be greater than a width of the first hole.

According to one or more embodiments of the present specification, the adhesive layer can include a body portion provided on an insulating layer of the touch sensor layer and a lens portion formed to protrude from the body portion, and the lens portion can be provided inside the second hole.

According to one or more embodiments of the present specification, the display panel can further include a color filter layer provided on the adhesive layer, the color filter layer can include a color filter and a black matrix, and the black matrix of the color filter layer can have a second hole overlapping the first hole.

According to one or more embodiments of the present specification, the adhesive layer can include a body portion provided on an insulating layer of the touch sensor layer and a lens portion formed to protrude from the body portion, and the second hole can overlap the lens portion.

According to one or more embodiments of the present specification, the plurality of wires can include a first light-transmission wire and a second light-transmission wire spaced apart from each other on a radial direction with a center of the light-transmission area as a reference, and a first light-transmission hole formed in the first light-transmission wire and a second light-transmission hole formed in the second light-transmission wire can be provided not to overlap each other.

According to one or more embodiments of the present specification, the plurality of wires can include a first light-transmission wire and a second light-transmission wire spaced apart from each other on a radial direction with a center of the light-transmission area as a reference, and a first light-transmission hole formed in the first light-transmission wire and a second light-transmission hole formed in the second light-transmission wire can form a predetermined angle with a center of the light-transmission area as a reference.

According to one or more embodiments of the present specification, the wire can be a touch wire.

According to one or more embodiments of the present specification, a moisture permeation prevention structure that is provided on the substrate to have a predetermined height can be provided in the boundary area, and the moisture permeation prevention structure can include a plurality of protrusion patterns spaced apart from each other.

According to one or more embodiments of the present specification, the moisture permeation prevention structure can further include a dam, and the plurality of protrusion patterns can include a plurality of first protrusion patterns provided between the display area and the dam, and plurality of second protrusion patterns provided between the dam and the light-transmission area.

According to one or more embodiments of the present specification, the display panel can further include a lens portion that is provided in a groove formed to be recessed in an upper surface of the insulating layer, and an adhesive layer can be provided on the lens portion. The adhesive layer and the lens portion can be made of different materials.

A display device according to one or more embodiments of the present specification can include a display panel including a display area, a light-transmission area, and a boundary area surrounding the light-transmission area; and a sensor, in which the display panel can include a substrate, a circuit layer provided on the substrate, a light-emitting element layer provided on the circuit layer, an encapsulation layer provided on the light-emitting element layer, a touch sensor layer disposed on the encapsulation layer, and an adhesive layer provided on the touch sensor layer, the adhesive layer includes a body portion and a lens portion formed to protrude from a lower portion of the body portion, at least one of a plurality of wires provided in the boundary area has a first hole overlapping the sensor, and the sensor can overlap the lens portion and the first hole.

According to one or more embodiments of the present specification, the sensor can include a first sensor overlapping the light-transmission area and a second sensor overlapping the first hole, and the second sensor can be an infrared sensor.

According to one or more embodiments of the present specification, the display panel can further include a black matrix provided below the adhesive layer, and the black matrix can have a second hole overlapping the first hole.

According to one or more embodiments of the present specification, the display panel can further include a color filter layer provided on the adhesive layer, the color filter layer can include a color filter and a black matrix, and the black matrix of the color filter layer can have a second hole overlapping the first hole.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a display panel including a display area, a light-transmission area, and a boundary area adjacent to the light-transmission area,
wherein the display panel includes:
a substrate;
a circuit layer provided on the substrate;
a light-emitting element layer provided on the circuit layer;
an encapsulation layer provided on the light-emitting element layer;
a touch sensor layer provided on the encapsulation layer; and
an adhesive layer provided on the touch sensor layer, and
wherein at least one of a plurality of wires provided in the boundary area has a first hole.

2. The display device according to claim 1, wherein:
the at least one of the plurality of wires includes a curved portion provided in a vicinity of the light-transmission area, and
the first hole is provided in the curved portion.

3. The display device according to claim 1, further comprising a sensor,
wherein the sensor includes a first sensor overlapping the light-transmission area and a second sensor overlapping the first hole, and
the second sensor includes an infrared sensor.

4. The display device according to claim 3, wherein:
the light-transmission area includes a first light-transmission area and a second light-transmission area spaced apart from each other, and
the second sensor overlaps the display area provided between the first light-transmission area and the second light-transmission area.

5. The display device according to claim 1, wherein:
the adhesive layer includes a body portion provided on an insulating layer of the touch sensor layer and a lens portion formed to protrude from the body portion, and
the lens portion of the adhesive layer overlaps the first hole.

6. The display device according to claim 5, further comprising a sensor,
wherein the sensor includes a first sensor overlapping the light-transmission area and a second sensor overlapping the first hole, and
the lens portion of the adhesive layer is convex toward the second sensor.

7. The display device according to claim 6, wherein the lens portion of the adhesive layer is provided in a groove formed to be recessed in an upper surface of the insulating layer of the touch sensor layer.

8. The display device according to claim 1, wherein:
the display panel further includes a black matrix provided below the adhesive layer, and
the black matrix has a second hole overlapping the first hole.

9. The display device according to claim 8, wherein a width of the second hole is greater than a width of the first hole.

10. The display device according to claim 8, wherein:
the adhesive layer includes a body portion provided on an insulating layer of the touch sensor layer and a lens portion formed to protrude from the body portion, and
the lens portion of the adhesive layer is provided inside the second hole.

11. The display device according to claim 1, wherein:
the display panel further includes a color filter layer provided on the adhesive layer,
the color filter layer includes a color filter and a black matrix, and
the black matrix of the color filter layer has a second hole overlapping the first hole.

12. The display device according to claim 11, wherein:
the adhesive layer includes a body portion provided on an insulating layer of the touch sensor layer and a lens portion formed to protrude from the body portion, and
the second hole overlaps the lens portion of the adhesive layer.

13. The display device according to claim 1, wherein:
the plurality of wires include a first light-transmission wire and a second light-transmission wire spaced apart from each other on a radial direction with a center of the light-transmission area as a reference, and
a first light-transmission hole formed in the first light-transmission wire and a second light-transmission hole formed in the second light-transmission wire are provided not to overlap each other in the radial direction.

14. The display device according to claim 1, wherein the at least one of the plurality of wires includes a touch wire.

15. The display device according to claim 1, further comprising:
a moisture permeation prevention structure provided on the substrate in the boundary area to have a predetermined height,
wherein the moisture permeation prevention structure includes a plurality of protrusion patterns spaced apart from each other.

16. The display device according to claim 15, wherein the moisture permeation prevention structure further includes a dam, and
wherein the plurality of protrusion patterns include:
a plurality of first protrusion patterns provided between the display area and the dam; and
a plurality of second protrusion patterns provided between the dam and the light-transmission area.

17. A display device comprising:
a display panel including a display area, a light-transmission area, and a boundary area; and
a sensor,
wherein the display panel includes:
a circuit layer provided on a substrate;
a light-emitting element layer provided on the circuit layer;
an encapsulation layer provided on the light-emitting element layer;
a touch sensor layer provided on the encapsulation layer; and
an adhesive layer provided on the touch sensor layer, and
wherein:
the adhesive layer includes a body portion and a lens portion formed to protrude from a lower portion of the body portion,
at least one of a plurality of wires provided in the boundary area has a first hole overlapping the sensor, and
the sensor overlaps the lens portion of the adhesive layer and the first hole of the at least one of the plurality of wires.

18. The display device according to claim 17, wherein:
the sensor includes a first sensor overlapping the light-transmission area and a second sensor overlapping the first hole, and
the second sensor includes an infrared sensor.

19. The display device according to claim 17, wherein:
the display panel further includes a black matrix provided below the adhesive layer, and
the black matrix has a second hole overlapping the first hole of the at least one of the plurality of wires.

20. The display device according to claim 17, wherein:
the display panel further includes a color filter layer provided on the adhesive layer,
the color filter layer includes a color filter and a black matrix, and
the black matrix of the color filter layer has a second hole overlapping the first hole of the at least one of the plurality of wires.
